(19) United States
(12) Patent Application Publication
(10) Pub. No.: US 2010/0008129 A1
(43) Pub. Date: Jan. 14, 2010

(54) SEMICONDUCTOR MEMORY DEVICE AND METHOD OF CONTROLLING THE SAME

(75) Inventor: Kazuhiro TERAMOTO, Tokyo (JP)

Correspondence Address: MORRISON & FOERSTER LLP, 1650 TYSONS BOULEVARD, SUITE 400, MCLEAN, VA, 22102, US

(73) Assignee: Elpida Memory, Inc., Tokyo (JP)

(21) Appl. No.: 12/501,250

(22) Filed: Jul. 10, 2009

(30) Foreign Application Priority Data
Jul. 14, 2008 (JP) 2008-182843

(51) Int. Cl. G11C 11/24; G11C 7/06; G11C 5/02

(52) U.S. Cl. 365/149; 365/207; 365/51

(57) ABSTRACT

A semiconductor memory device includes first and second bit lines complementary to each other, sense amplifiers, memory cells, first and second switches, an equalizer circuit, and a potential generation unit. The potential generation unit supplies a first potential to at least a selected one of the plurality of first and second bit lines through the plurality of first and second switches. The equalizer circuit sets the first and second bit lines at the second potential. When an access to the memory cell connected to the first and second bit lines, the potential generation unit gives the first potential to the second bit line.

### BACKGROUND OF THE INVENTION

1. Field of the Invention

The present invention relates to a semiconductor memory device, and more particularly relates to memory access techniques with respect to a dynamic random access memory, hereinafter referred to as a DRAM.

Priority is claimed on Japanese Patent Application No. 2008-182843, filed Jul. 14, 2008, the content of which is incorporated herein by reference.

2. Description of the Related Art

In recent years, a power supply voltage supplied to a semiconductor memory device such as a DRAM has been lowered due to an advancement of minute processing techniques and lowering of power consumption. A voltage supplied to a memory array in the DRAM is also lowered, for example from 1.8 V to 1.4 V, and to 1.2 V, and further to 1.0 V. On the other hand, it is difficult to decrease a threshold voltage of a MOS transistor in proportion to the lowering of the power supply voltage because of variations caused in fabrication processes. To perform a normal operation of an N-channel transistor in the memory array, a voltage of a gate of the N-channel transistor should be equal to or more than 0.5 V.

In a related art, half of the power supply voltage is precharged to a bit line, and a data value stored in a memory cell is detected based on the half of the power supply voltage. But there is little difference between the threshold voltage of the MOS transistor constituting a sense amplifier and the precharged voltage, and a potential difference between a gate and a source of the MOS transistor is not sufficient. The time in an amplifying operation of the sense amplifier becomes longer, and the speed of a reading operation is not sufficient. Japanese Patent Application No. 2004-265533 discloses that, in order to solve the above problem of the lowered power supply voltage, a technique of precharging the bit line connected to the sense amplifier with the power supply voltage before the reading operation is performed.

But a dummy capacitor in a dummy cell is difficult to have a stable reference potential because of the variations caused in the fabrication processes along with the advancement of the minute processing techniques. An extra memory cell is disposed on a memory mat to replace a defective memory cell in the memory mat, but the dummy cell and the memory cell cannot be exchanged because a capacitance of the dummy capacitor in the dummy cell and a capacitance of a capacitor in the memory cell are different.

Japanese Patent Application No. 2004-265533 also discloses the memory mat having the dummy cell, wherein a cell pattern becomes discontinuous at an end of the memory mat during the minute process for the variations of the capacitance of the dummy cell. As a result, the dummy capacitor in the dummy cell is difficult to have the stable reference potential, and causes the variations of the speed of reading of data in the DRAM and decrease in performance of the DRAM.

### SUMMARY

A semiconductor memory device includes a plurality of first bit lines, a plurality of second bit lines, each of the plurality of second bit lines being complementary to a respective one of the plurality of first bit lines, a plurality of sense amplifiers, each of the plurality of sense amplifiers being connected to a respective one of pairs of the first and second bit lines, a plurality of memory cells, each of the plurality of memory cells being connected to a respective one of the plurality of first bit lines, a plurality of first switches, each of the plurality of first switches being connected to a respective one of the plurality of first bit lines, a plurality of second switches, each of the plurality of second switches being connected to a respective one of the plurality of second bit lines, an equalizer circuit that is connected to the plurality of first and second bit lines, and a potential generation unit that is connected to the plurality of first bit lines through the plurality of first switches, the potential generation unit being connected to the plurality of second bit lines through the plurality of second switches, the potential generation unit supplying a first potential to at least a selected one of the plurality of first and second bit lines through the plurality of first and second switches. The equalizer circuit sets the plurality of first and second bit lines at the second potential. When each of the plurality of memory cells is selected, the potential generation unit applies the first potential to a corresponding second bit line through a corresponding second switch, the corresponding second bit line being paired with a corresponding first bit line, the corresponding first bit line being connected to the selected memory cell, the corresponding second switch being connected to the corresponding second bit line. A corresponding sense amplifier performs sensing of a third potential of the corresponding first bit line and a fourth potential of the corresponding second bit line, the corresponding sense amplifier being connected to the corresponding first and second bit lines, the third potential being a potential charge-shared between an information potential of the selected memory cell and the first potential, the fourth potential being a potential charge-shared between the first potential and total of all the second potentials of all the plurality of second bit lines.

A semiconductor memory device includes a plurality of memory cells, a plurality of first bit lines, each of the plurality of first bit lines transmitting information of a respective one of the plurality of memory cells, a plurality of second bit lines, each of the plurality of second bit lines performing as a reference potential line that is needed in sensing of a respective one of the plurality of first bit lines, a plurality of sense amplifiers, each of the plurality of sense amplifiers connected to a respective one of the plurality of first bit lines and a respective one of the plurality of second bit lines, a plurality of switches, each of the plurality of switches connected to a respective one of the plurality of second bit lines, and a potential generation unit that is connected to the first side of each of the plurality of switches. The potential generation unit comprises a capacitor that accumulates an amount of charge. The capacitor is to be charge-shared with a total amount of charges of the plurality of second bit lines. The second bit line is set at a first potential when the plurality of switches turn ON. The first potential is a half of the total of different potentials of the plurality of first bit lines, the different potentials respectively corresponding binary information 0 and 1 of the plurality of memory cells.

A semiconductor memory device includes a first bit line, a second bit line being complementary to the first bit line, a sense amplifier being connected to a pair of the first and second bit lines, a memory cell being connected to the first bit line, a first switch being connected to the first bit line, a second switch being connected to the second bit line, an equalizer circuit that is connected to the first and second bit lines, and a potential generation unit that is connected to the first bit line through the first switch, the potential generation unit being connected to the second bit line through the second switch, the potential generation unit supplying a first potential to at least a selected one of the first and second bit lines through the first and second switches. The equalizer circuit sets the first and second bit lines at the second potential. Potential of the second bit line becomes a charge-shared potential between the first potential and all the second potentials of all the second bit lines, the second bit line being corresponding to the first bit line connected to the memory cell.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a view of a block diagram illustrating a configuration of a semiconductor memory device in accordance with a first embodiment of the present invention.

FIG. 2 is a view of a block diagram illustrating a configuration of a memory mat column and a connection between the memory mat column and a potential generation unit in the semiconductor memory device of FIG. 1;

FIG. 3 is a view of a block diagram illustrating a configuration of a memory mat and a potential generation unit, the memory mat being arranged in an open bit line configuration, and illustrating a connection between the memory mat and the potential generation unit in accordance with the first embodiment;

FIG. 4 is a timing chart illustrating an outline of a signal transition in a first behavior of reading in accordance with the first embodiment;

FIG. 5 is a timing chart illustrating an outline of a signal transition in a second behavior of reading in accordance with the first embodiment;

FIG. 6 is a graph showing a relationship between a capacitance CL and a storage potential VL in accordance with the first embodiment; and

FIG. 7 is a view of a block diagram illustrating a configuration of a memory mat and a potential generation unit, the memory mat being arranged in a folded bit line configuration, and illustrating a connection between the memory mat and the potential generation unit in accordance with the second embodiment.

### DETAILED DESCRIPTION OF THE PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purpose.

The potential generation unit of the semiconductor memory device is disposed out of the memory mat. The potential generation unit generates the reference potential that is given by the charge share with one of paired bit lines connected to the plurality of the sense amplifiers. The other of the paired bit lines connected to the plurality of the sense amplifiers is applied with the reference potential.

So the potential generation unit need not be disposed on the restricted area in the memory mat, and the semiconductor memory device with a stable capacitance can be fabricated. The extra capacitor adjusting the capacitance can be disposed if the potential generation unit is disposed out of the memory mat, so the reference potential can be adjusted by adjusting capacitances of the capacitors in the potential generation unit even after the fabrication. As a result, even if the potential used in the memory array is small, the stable reference potential can be output to the sense amplifier by preparing the capacitor with constant capacitance along with the minute processing techniques and the lowering of the power consumption. Then the reading speed becomes stable and the decrease in performance can be avoided.

A first embodiment of the present invention will be described with reference to the drawings.

### First Embodiment

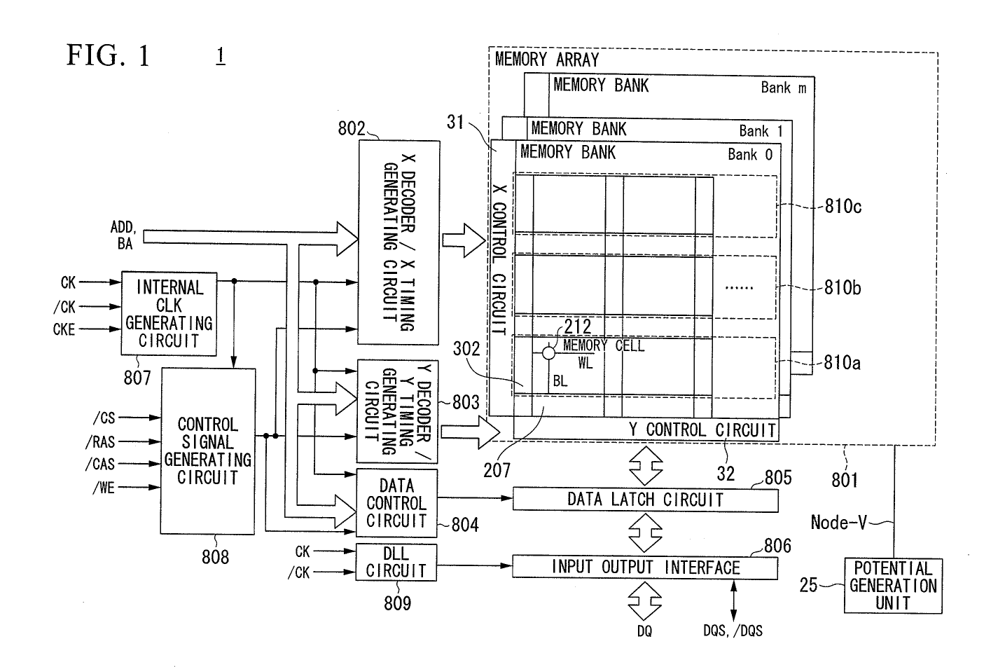

FIG. 1 is a view of a block diagram illustrating a configuration of a semiconductor memory device 1 in accordance with the first embodiment. A synchronous dynamic random access memory, hereinafter referred to as an SDRAM, is used here. The semiconductor memory device 1 includes an internal clock generating circuit 807, a control signal generating circuit 808, an X decoder/X timing generating circuit 802, a Y decoder/Y timing generating circuit 803, a data control circuit 804, a delay locked loop circuit 809 that is hereinafter referred to as DLL circuit 809, a memory array 801, a data latch circuit 805, an input output interface 806 and a potential generation unit 25.

The internal clock generating circuit 807 receives a clock signal CK, an inverted clock signal /CK that is an inverted signal of the clock signal CK and a clock enable signal CKE that shows whether the clock signal CK and the inverted clock signal /CK are valid or not. The internal clock generating circuit 807 outputs an internal clock signal based on the clock signal CK, the inverted clock signal /CK and the clock enable signal CKE.

The control signal generating circuit 808 receives a chip select signal /CS, a row address strobe signal /RAS, a column address strobe signal /CAS and a write enable signal /WE, and performs decoding of these received signals. Then the control signal generating circuit 808 outputs a control signal that instructs an operation to the X decoder/X timing generating circuit 802, the Y decoder/Y timing generating circuit 803 and the data control circuit 804 based on result of the decoding.

The memory array 801 includes a plurality of memory banks Bank 0, Bank 1, - - - , Bank m. Each of the memory banks Bank 0, Bank 1, - - - , Bank m respectively includes an X control circuit 31, a Y control circuit 32, a plurality of sub-word driver circuits 302, a plurality of sense amplifier columns 207 and a plurality of memory mat columns 810a, 810b, 810c, - - - . Each of the memory mat columns 810a, 810b, 810c, - - - respectively includes a plurality of memory mats. Each of the memory mats includes a plurality of memory cells. Each of the sense amplifier columns 207 includes a plurality of sense amplifiers. The memory mat columns 810a, 810b, 810c, - - - have the same configuration each other, and hereinafter may be referred to as the memory mat columns 810.

The X decoder/X timing generating circuit 802 receives an address signal ADD and a bank signal BA, and performs decoding of the received signals, the address signal ADD output from an external device and including a row address. The X decoder/X timing generating circuit 802 selects a first recording area of the memory array 801 based on result of the decoding, using a word line WL that is disposed on each of the memory mat columns 810. That is, the X decoder/X timing generating circuit 802 performs control of the operation of reading and writing of data in the first recording area based on the control signal from the control signal generating circuit 808, the operation synchronized with the internal clock signal from the internal clock generating circuit 807.

The Y decoder/Y timing generating circuit 803 receives the address signal ADD and the bank signal BA, and performs decoding of the received signals, the address signal ADD output from the external device and including a column address. The Y decoder/Y timing generating circuit 803 selects a second recording area from the first recording area selected by the X decoder/X timing generating circuit 802 based on result of the decoding. That is, the Y decoder/Y timing generating circuit 803 performs control of the operation of reading and writing of data in the second recording area based on the control signal from the control signal generating circuit 808, the operation synchronized with the internal clock signal from the internal clock generating circuit 807.

The data control circuit 804 receives the address signal ADD and the bank signal BA, and performs decoding of the received signals. The data control circuit 804 performs control of timing for latching of data by the data latch circuit 805 based on result of the decoding and the control signal from the control signal generating circuit 808.

The data latch circuit 805 receives a readout data from the memory array 801, and latches the readout data to generate a latched data, the latched data output to the input output interface 806. The data latch circuit 805 receives a write data from the input output interface 806, and latches the write data to generate a latched data, the latched data output to the memory array 801.

The DLL circuit 809 receives the clock signal CK and the inverted clock signal /CK, and outputs a DLL clock signal to the input output interface 806, the DLL clock signal synchronized with the clock signal CK and the inverted clock signal /CK.

The input output interface 806 receives the latched data signal from the data latch circuit 805, the receiving synchronized with the DLL clock signal from the DLL circuit 809. The input output interface 806 outputs a data signal DQ and paired data strobe signals DQS and /DQS to an external device, the outputting synchronized with the DLL clock signal from the DLL circuit 809, the paired data strobe signals showing timing for the external device to receive the data signal DQ.

The input output interface 806 receives the data signal DQ from the external device, the receiving synchronized with the paired data strobe signals DQS and /DQS from the external device. The input output interface 806 outputs the received data signal DQ to the data latch circuit 805, the outputting synchronized with the DLL clock signal from the DLL circuit 809.

The potential generation unit 25 accumulates a charge to apply a reference potential Vref that is a standard in reading of data in the sense amplifier 203. When the potential generation circuit 25 is connected to a bit line that is connected to the plurality of the sense amplifiers 203 to transfer the accumulated charge from the potential generation circuit 25 to the bit line BL, the amount of charge applied to the bit line BL becomes equal to the reference potential Vref.

The X decoder/X timing generating circuit 802 receives the address signal ADD from the external device, and performs decoding of the row address in the received address signal ADD. The Y decoder/Y timing generating circuit 803 receives the address signal ADD from the external device, and performs decoding of the column address in the received address signal ADD. The X decoder/X timing generating circuit 802 and the Y decoder/Y timing generating circuit 803 select a word line WL and a bit line BL in the memory banks Bank 0, Bank 1, - - - , Bank m of the memory array 801 based on results of the decodings, and specify a memory cell 212 disposed on the intersection of the selected word line WL and the selected bit line BL, so that an access is made to the memory cell 212, thereby reading or writing data in the specified memory cell 212.

The specified memory cells 212 are connected to different bit lines BL each other. Data in the specified memory cells 212 are output to different sense amplifiers 207 through the different bit lines BL. The sense amplifier 207 receives and amplifies the data. The Y control circuit 32 selects data of the amplified data, and outputs the selected data to the data latch circuit 805, controlled by the Y decoder/Y timing generating circuit 803.

The data latch circuit 805 receives a data from the memory array 801, and performs latching of the received data, and outputs the latched data to the input output interface 806. The input output interface 806 receives the latched data from the data latch circuit 805 to generate a data DQ, and outputs the data DQ and paired data strobe signals DQS and /DQS to the external device based on the clock signal from the DLL circuit 809.

As described above, the X decoder/X timing generating circuit 802 and the Y decoder/Y timing generating circuit 803 select the second recording area specified by the address signal ADD and the bank signal BA from recording areas of the memory array 801.

The configuration of the memory mat column will be described.

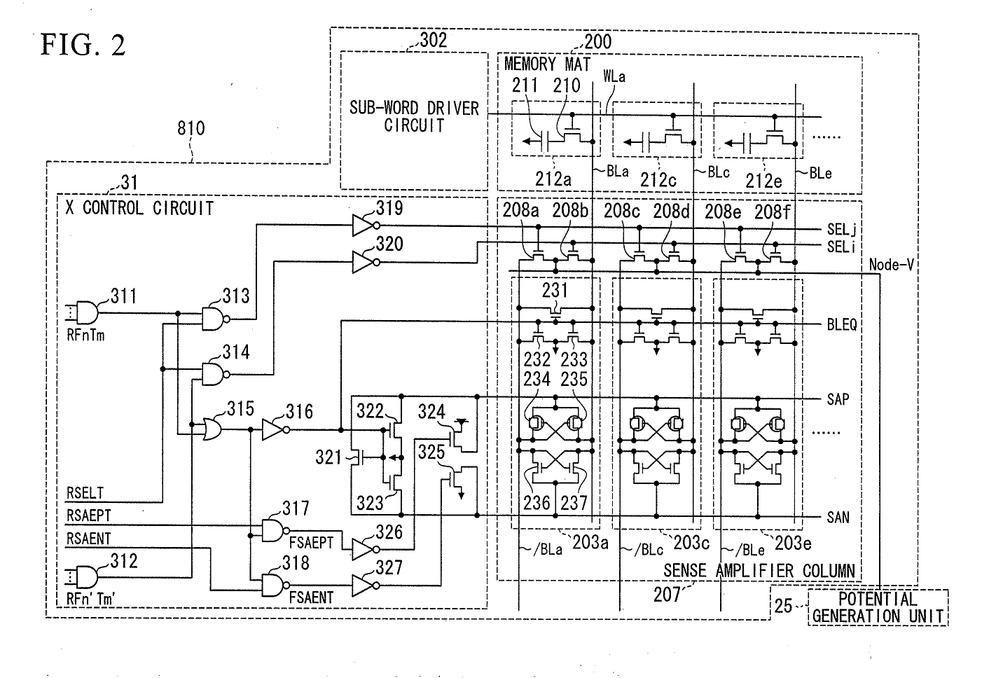

FIG. 2 is a view of a block diagram illustrating a configuration of the memory mat column 810 and a connection between the memory mat column 810 and the potential generation unit 25 in the semiconductor memory device 1 of FIG. 1.

The memory mat column 810 includes the X control circuit 31, the sub-word driver circuit 302, the memory mat 200 and the sense amplifier column 207. The sense amplifier column 207 is connected to the potential generation unit 25 by a node line Node-V. The memory mat column 810 includes a plurality of the memory mats 200 though not shown in FIG. 2. And the memory mat column 810 includes a plurality of the X control circuits 31, a plurality of the sub-word driver circuits 302 and a plurality of the sense amplifier columns 207 respectively corresponding to the plurality the memory mats 200 though not shown in FIG. 2.

The memory mat 200 includes a plurality of memory cells 212a, 212c, 212e, - - - . Each of the memory cells 212a, 212c, 212e, - - - are disposed on intersections of corresponding bit lines BLa, BLc, BLe, - - - and a word line WLa.

The memory cell 212a includes a memory cell capacitor 211 and a memory cell transistor 210. The memory cell capacitor 211 has a first and second sides. The first side is connected to ground, that is, applied with a ground potential VSS. The second side is connected to a source of the memory cell transistor 210. The memory cell transistor 210 is an N-channel transistor. A gate of the memory cell transistor 210 is connected to the word line WLa. A drain of the memory cell transistor 210 is connected to the bit line BLa corresponding to the memory cell 212a.

The memory cells 212a, 212c, 212e, - - - have the same configuration each other, and hereinafter may be referred to as the memory cells 212.

The X control circuits 31 receives memory mat column select signals RFnTm and RFn′Tm′ that are made of a plurality of signals, a reference activating signal RSELT and sense amplifier activating signals RSAEPT and RSAENT from the X decoder/X timing generating circuit 802.

The memory mat column select signals RFnTm and RFn′Tm′ select a memory mat column based on result of decoding of the row address by the X decoder/X timing generating circuit 802. The reference activating signal RSELT defines timing for applying the reference potential Vref to the sense amplifier column 207. The sense amplifier activating signals RSAEPT and RSAENT defines timing for activating the sense amplifiers 203a, 203c, 203e, - - - disposed on the sense amplifier column 207.

The X control circuits 31 includes multi-input AND gates 311 and 312, two-input NAND gates 313, 314, 317 and 318, a two-input OR gate 315, inverters 316, 319, 320, 326 and 327 and N-channel transistors 321, - - - , 325. The memory mat column select signals RFnTm and RFn′Tm′ are made of a plurality of signals, corresponding to each of the memory mats 200. When all of the plurality of the signals in the memory mat column select signals RFnTm or RFn′Tm′ are in “H” level, a memory mat corresponding to the memory mat column select signals RFnTm or RFn′Tm′ is selected. For example, when all of the plurality of the signals in the memory mat column select signals RFnTm are in “H” level and at least one of the plurality of the signals in the memory mat column select signals RFn′Tm′ is in “L” level, the memory mat 200 corresponding to the memory mat column select signals RFnTm and RFn′Tm′ is selected.

The multi-input AND gate 311 receives the memory mat column select signals RFnTm from the X decoder/X timing generating circuit 802, performs AND operation to the received signals, and outputs result of the operation to the NAND gate 313 and the OR gate 315. The multi-input AND gate 312 receives the memory mat column select signals RFn′Tm′ from the X decoder/X timing generating circuit 802, performs AND operation to the received signals, and outputs result of the operation to the NAND gate 314 and the OR gate 315. The two-input NAND gate 313 receives signal from the multi-input AND gate 311 and the reference activating signal RSELT, performs NAND operation to the received signals, and outputs result of the operation to the inverter 319. The two-input NAND gate 314 receives signal from the multi-input AND gate 312 and the reference activating signal RSELT, performs NAND operation to the received signals, and outputs result of the operation to the inverter 320.

The two-input OR gate 315 receives signal from the multi-input AND gate 311 and the multi-input AND gate 312, performs OR operation to the received signals, and outputs result of the operation to the inverter 316, the two-input NAND gates 317 and 318. The inverter 316 receives signal from the two-input OR gate 315, performs NOT operation to the received signal, and outputs result of the operation to the sense amplifier column 207 as a precharge signal BLEQ and gate of the N-channel transistors 321, 322 and 323. The two-input NAND gate 317 receives the sense amplifier activating signal RSAEPT and signal from the two-input OR gate 315, performs NAND operation of the received signals, and outputs result of the operation to the inverter 326 as a signal FSAEPT. The two-input NAND gate 318 receives the sense amplifier activating signal RSAENT and signal from the two-input OR gate 315, performs NAND operation of the received signals, and outputs result of the operation to the inverter 327 as a signal FSAENT.

The inverter 319 receives signal from the two-input NAND gate 313, performs NOT operation to the received signal, and outputs result of the operation to the sense amplifier column 207 as a bit select signal SELj. The inverter 320 receives signal from the two-input NAND gate 314, performs NOT operation to the received signal, and outputs result of the operation to the sense amplifier column 207 as a bit line select signal SELi.

Gates of the N-channel transistors 321, 322 and 323 are connected to the inverter 316. The gates receive an output signal from the inverter 316. Either of source or drain of the N-channel transistor 321 and drain of the N-channel transistor 322 are connected to a higher-potential drive wiring SAP, the other of source or drain of N-channel transistor 321 and drain of the N-channel transistor 323 are connected to a lower-potential drive wiring SAN, and sources of the N-channel transistors 322 and 323 are connected to a ground potential VSS (equalizing potential level). When the output signal from the inverter 316 is in “H” level, the N-channel transistors 321, 322 and 323 connect the higher-potential drive wiring SAP with the lower-potential drive wiring SAN, and applies a ground potential VSS to the lower-potential drive wiring SAN and the higher-potential drive wiring SAP.

A gate of the N-channel transistor 324 is connected to the inverter 326, and receives an output signal from the inverter 326. When the output signal from the inverter 326 is in “H” level, the N-channel transistor 324 applies a higher potential VARY to the higher-potential drive wiring SAP.

A gate of the N-channel transistor 325 are connected to the inverter 327, and receives an output signal from the inverter 327. When the output signal from the inverter 327 is in “H” level, the N-channel transistor 325 applies the ground potential VSS to the lower-potential drive wiring SAN.

The higher potential VARY equals to potential caused by decreasing voltage of power supply potential VDD applied to the semiconductor memory device 1 using a voltage divider circuit.

As described above, the memory mat 200 controlled by the X control circuit 31 are selected by the memory mat column select signals RFnTm and RFn′Tm′, then the X control circuit 31 performs control of the sense amplifier column 207. The sub-word driver circuit 302 applies potential to the word line WLa, and connects memory cells 212a, 212c, 212e, - - - to the corresponding bit lines BLa, BLc, BLe, - - - .

The sense amplifier column 207 includes a plurality of sense amplifiers 203a, 203b, 203c, - - - and connecting transistors 208a, 208b, 208c, - - - disposed on the sense amplifiers 203a, 203b, 203c, - - - and the node line Node-V.

The sense amplifiers 203a, 203c, 203e, - - - are disposed on the sense amplifier column 207, corresponding to the bit lines BLa, BLc, BLe, - - - . The sense amplifiers 203a, 203c, 203e, - - - are connected to the bit lines /BLa, /BLc, /BLe, - - - that are paired with the bit lines BLa, BLc, BLe, - - - .

The connecting transistors 208b, 208d, 208f, - - - are first switches.

The connecting transistors 208b, 208d, 208f, - - - are disposed between the bit lines BLa, BLc, BLe, - - - and the node line Node-V. The bit line select signal SELi is applied to gates of the connecting transistors 208b, 208d, 208f, - - - . The connecting transistors 208b, 208d, 208f, - - - switch on/off based on the bit line select signal SELi. Each of the connecting transistors 208b, 208d, 208f, - - - turns “on” to connect a respective one of the bit lines BLa, BLc, BLe, - - - to the node line Node-V connected to the potential generation unit 25. Each of the connecting transistors 208b, 208d, 208f, turns “off” to disconnect the respective one of the bit lines BLa, BLc, BLe, - - - from the node line Node-V connected to the potential generation unit 25. The connecting transistors 208b, 208d, 208f, - - - perform as switches, each of which connects a respectively one of the bit lines BLa, BLc, BLe, - - - to the potential generation unit 25 and disconnects the both from each other.

The connecting transistors 208a, 208c, 208e, - - - are second switches.

The connecting transistors 208a, 208c, 208e, - - - are disposed between the bit lines /BLa, /BLc, /BLe, - - - and the node line Node-V. The bit line select signal SELj is applied to gates of the connecting transistors 208a, 208c, 208e, - - - . The connecting transistors 208a, 208c, 208e, - - - switch on/off based on the bit line select signal SELj. Each of the connecting transistors 208a, 208c, 208e, - - - turns “on” to connect a respective one of the bit lines /BLa, /BLc, /BLe, - - - to the node line Node-V connected to the potential generation unit 25. Each of the connecting transistors 208a, 208c, 208e, turns “off” to disconnect the respective one of the bit lines /BLa, /BLc, /BLe, - - - from the node line Node-V connected to the potential generation unit 25. The connecting transistors 208a, 208c, 208e - - - perform as switches, each of which connects a respectively one of the bit lines /BLa, /BLc, /BLe, - - - to the potential generation unit 25 and disconnects the both from each other.

The bit lines BLa, BLb, BLc, - - - have the same configuration each other, and hereinafter may be referred to as the bit lines BL. The bit lines /BLa, /BLb, /BLc, - - - have the same configuration each other, and hereinafter may be referred to as the bit lines /BL.

The sense amplifier 203a includes N-channel transistors 231, - - - , 237 and P-channel transistors 234 and 235. Either of a source or a drain of the N-channel transistor 231 is connected to the bit line BLa, and the other of a source or a drain of the N-channel transistor 231 is connected to the bit line /BLa. A gate of the N-channel transistor 231 is connected to the precharge signal BLEQ from the X control circuit 31.

Either of a source or a drain of the N-channel transistor 232 is connected to the bit line /BLa, and the other of source or drain of the N-channel transistor 232 is connected to the ground potential and either of a source or a drain of the N-channel transistor 233. A gate of the N-channel transistor 232 is connected to the precharge signal BLEQ from the X control circuit 31.

Either of a source or a drain of the N-channel transistor 233 is connected to the bit line BLa, and the other of source or drain of the N-channel transistor 233 is connected to the ground potential and either of a source or a drain of the N-channel transistor 232. A gate of the N-channel transistor 233 is connected to the precharge signal BLEQ from the X control circuit 31.

When the precharge signal BLEQ is in “H” level, the N-channel transistors 231, 232 and 233 switch on, and the ground potential VSS (equalizing potential level) is applied to the bit lines BLa and /BLa. That is, the bit lines BLa and /BLa are precharged with the ground potential VSS.

When the precharge signal BLEQ is in “L” level, the N-channel transistors 231, 232 and 233 switch off, and the bit lines BLa and /BLa are disconnected from each other. When the bit select signal SELj is in “H” level, the transistors 208a, 208c, 208e, 208g, - - - switch on, and the node line Node-V is connected to the bit lines /BLa, /BLc, /BLe, /BLg, - - - through the transistors 208a, 208c, 208e, 208g, - - - , respectively. Charge share is performed between the node line Node-V and the bit lines /BLa, /BLc, /BLe, /BLg, - - - . Potential of the potential generation unit 25 is supplied to the bit lines /BLa, /BLc, /BLe, /BLg, - - - . Since the bit lines BLa and /BLa are disconnected from each other, the bit lines /BLa, /BLc, /BLe, /BLg, - - - are transitioned from the ground potential VSS to the potential of the potential generation unit 25. Then the potentials of the bit lines /BLa, /BLc, /BLe, /BLg, - - - become charge-shared potentials between the potentials of the bit lines /BLa, /BLc, /BLe, /BLg, - - - corresponding to the potential equalized by the precharge signal BLEQ and the potential of the node line Node-V charged in the capacitor 204. Charge is held in coulombs.

The N-channel transistors 231, 232 and 233 operate in combination as an equalizer circuit. The equalizer circuit sets the bit lines BLa, BLc, BLe, BLg, - - - and the bit lines /BLa, /BLc, /BLe, /BLg, - - - at the ground potential VSS (equalizing potential level) before the memory cell is accessed.

Any one of the first switches (transistors 208b, 208d, 208f) and second switches (transistors 208a, 208c, 208e) performs charge share between the node line Node-V and the bit lines BLa, BLc, BLe, BLg, - - - or the bit lines /BLa, /BLc, /BLe, /BLg, - - - .

Either of a source or a drain of the P-channel transistor 234 is connected to the higher-potential drive wiring SAP, and the other of source or drain of the P-channel transistor 234 is connected to a gate of the P-channel transistor 235 and the bit line /BLa.

Either of a source or a drain of the P-channel transistor 235 is connected to the higher-potential drive wiring SAP, and the other of source or drain of the P-channel transistor 235 is connected to a gate of the P-channel transistor 234 and the bit line BLa.

Either of a source or a drain of the N-channel transistor 236 is connected to the lower-potential drive wiring SAN, and the other of source or drain of the N-channel transistor 236 is connected to a gate of the N-channel transistor 237 and the bit line /BLa.

Either of a source or a drain of the N-channel transistor 237 is connected to the lower-potential drive wiring SAN, and the other of source or drain of the N-channel transistor 237 is connected to a gate of the N-channel transistor 236 and the bit line BLa.

That is, the P-channel transistors 234 and 235 are connected in cross-couple configuration, and the N-channel transistors 236 and 237 are connected in cross-couple configuration.

A potential corresponding to data recorded in the memory cell is applied to the sense amplifier 203a through either of the bit lines BLa or /BLa. The reference potential Vref is applied to the sense amplifier 203a through the other of the bit lines BLa or /BLa. The sense amplifier 203a amplifies a minute potential difference between the bit lines BLa and /BLa. Amplifying the minute potential difference is performed by the sense amplifier 203a for sensing each of the bit lines BLa and /BLa.

The sense amplifiers 203c, 203e, - - - have the same configuration as the sense amplifier 203a, and are connected to corresponding paired bit lines {BLc, /BLc}, {BLe, /BLe}, - - - , the precharge signal BLEQ, the higher-potential drive wiring SAP and the lower-potential drive wiring SAN.

The configuration of the memory mats and the sense amplifier, and connection between the memory mats and the sense amplifier columns will be described.

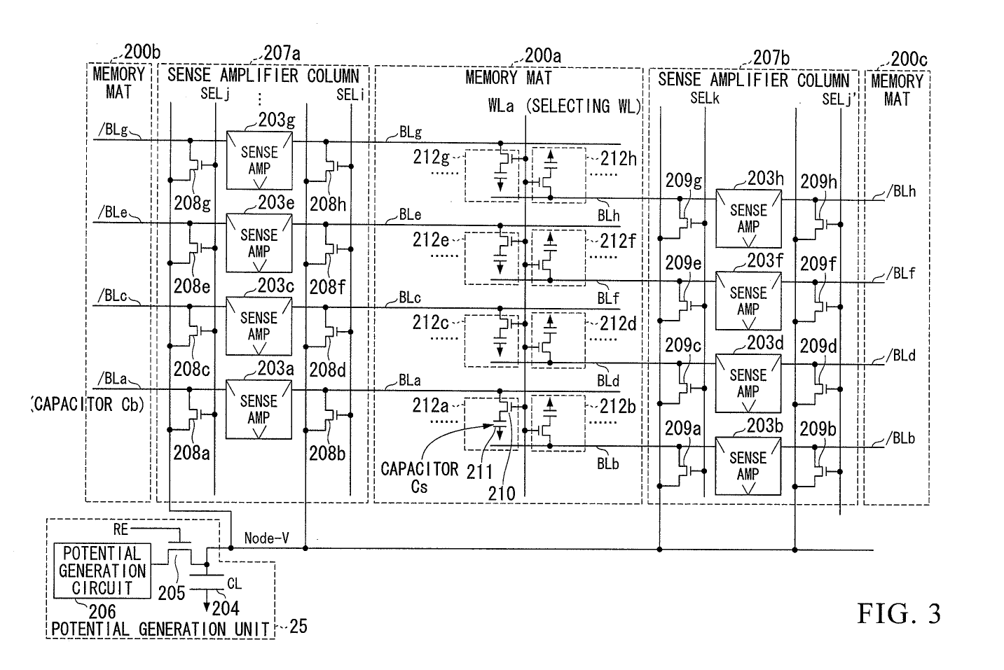

FIG. 3 is a view of a block diagram illustrating a configuration of the memory mats 200a, 200b and 200c that are arranged in an open bit line configurations, the sense amplifier columns 207a, 207b and the potential generation unit 25, and illustrating a connection between the memory mats 200a, 200b and 200c, the sense amplifier columns 207a, 207b and the potential generation unit 25 in accordance with the first embodiment. The open bit line configuration is such configuration that a paired bit lines connected to one sense amplifier 203 are disposed separately at memory mats of the both sides of the sense amplifier 203, respectively. The memory mats 200a, 200b and 200c have the same configuration as the memory mats 200 of FIG. 2. The sense amplifiers 207a and 207b have the same configuration each other.

The memory mat 200a is disposed between the sense amplifier 207a and the sense amplifier 207b. The memory mat 200b is disposed on opposite side of the memory mat 200a, the memory mats 200a and 200b sandwiching the sense amplifier column 207a. The memory mat 200c is disposed on opposite side of the memory mat 200a, the memory mats 200a and 200c sandwiching the sense amplifier column 207b.

The memory mat 200a includes a plurality of memory cells 212a, 212b, - - - . The memory mat 200a includes bit lines BLa, BLb, BLc, - - - corresponding to the plurality of memory cells 212a, 212b, - - - .

The memory cell 212a includes a memory cell capacitor 211 and a memory cell transistor 210. One end of the memory cell capacitor 211 is connected to the ground, and the other end of the memory cell capacitor 211 is connected to source of the memory cell transistor 210. The gate of the memory cell transistor 210 is connected to the word line WLa, and the drain of the memory cell transistor 210 is connected to the bit line BLa. The memory cell transistor 210 is a N-channel transistor.

The bit lines BLa, BLb, BLc, - - - are connected respectively to the memory cells 212a, 212b, 212c, - - - , and connected alternately to either the sense amplifier column 207a or the sense amplifier column 207b. Each of the memory cells 212b, 212c, - - - includes the memory capacitor 211 and the memory cell transistor 210 like the memory cell 212a. One end of the memory cell capacitor 211 is connected to the ground, and the other end of the memory cell capacitor 211 is connected to source of the memory cell transistor 210. The gate of the memory cell transistor 210 is connected to the word line WLa and gates of other memory cell transistors 210 of the memory cells 212b, 212c, - - - , and the drain of the memory cell transistor 210 is connected to bit line corresponding to each memory cell.

The memory mats 200b and 200c have the same configuration as the memory mats 200a. The memory mat 200b is disposed between the sense amplifier column 207a and another sense amplifier column that is not illustrated in the drawings. The memory mat 200c is disposed between the sense amplifier column 207b and another sense amplifier column that is not illustrated in FIG. 3.

The sense amplifier column 207a includes a plurality of the sense amplifiers 203a, 203c, 203e, 203g, - - - . The sense amplifiers 203a, 203c, 203e, 203g, - - - are respectively connected to the bit lines BLa, BLc, BLe, BLg - - - of the memory mat 200a and the bit lines /BLa, /BLc, /BLe, /BLg, - - - of the memory mat 200b. The connecting transistors 208b, 208d, 208f, 208h, - - - are disposed between the bit lines BLa, BLc, BLe, BLg, - - - that are connected to the memory mat 200a and the node line Node-V in the sense amplifier column 207a. The connecting transistors 208b, 208d, 208f, 208h, - - - defines whether to connect the bit lines BLa, BLc, BLe, BLg, - - - to the node line Node-V or not based on the bit line select signal SELi input from gate of the connecting transistors 208b, 208d, 208f, 208h, - - - . The connecting transistors 208a, 208c, 208e, 208g, - - - are disposed between the bit lines /BLa, /BLc, /BLe, /BLg, - - - and the node line Node-V in the sense amplifier column 207a. The connecting transistors 208a, 208c, 208e, 208g, - - - defines whether to connect the bit lines /BLa, /BLc, /BLe, /BLg, - - - to the node line Node-V or not based on the bit line select signal SELj input from gate of the connecting transistors 208a, 208c, 208e, 208g, - - - . The sense amplifiers 203a, 203c, 203e, 203g, - - - are connected to the precharge signal BLEQ, the higher-potential drive wiring SAP and the lower-potential drive wiring SAN that are connected to the X control circuit 31, as described in FIG. 2. The connecting transistors 208a, 208b, 208c, - - - are N-channel transistors.

The sense amplifier column 207b includes a plurality of the sense amplifiers 203b, 203d, 203f, 203h, - - - . The sense amplifiers 203b, 203d, 203f, 203h, - - - are respectively connected to the bit lines BLb, BLd, BLf, BLh,- - - in the memory mat 200a, and the bit lines /BLa, /BLc, /BLf, /BLh, - - - in the memory mat 200c. The connecting transistors 209a, 209c, 209e, 209g, - - - are disposed between the bit lines BLb, BLd, BLf, BLh, - - - that are connected to the memory mat 200a and the node line Node-V in the sense amplifier column 207b. The connecting transistors 209a, 209c, 209e, 209g, - - - defines whether to connect the bit lines BLb, BLd, BLf, BLh, - - - to the node line Node-V or not based on the bit line select signal SELk input from gate of the connecting transistors 209a, 209c, 209e, 209g, - - - . The connecting transistors 209b, 209d, 209f, 209h, - - - are disposed between the bit lines /BLb, /BLd, /BLf, /BLh, - - - and the node line Node-V in the sense amplifier column 207b. The connecting transistors 209b, 209d, 209f, 209h, - - - defines whether to connect the bit lines /BLb, /BLd, /BLf, /BLh, - - - to the node line Node-V or not based on the bit line select signal SELj′ input from gate of the connecting transistors 209b, 209d, 209f, 209h, - - - . The connecting transistors 209a, 209b, 209c, - - - are N-channel transistors. The bit line select signal SELj′ is applied a voltage in the same way as the bit line select signal SELj.

The potential generation unit 25 includes the capacitor 204, a potential generation circuit 206 and a changing switch 205 that is an N-channel transistor. One end of the capacitor 204 is connected to the ground, and the other end of the capacitor 204 is connected to either of a source or a drain of the changing switch 205 and the node line Node-V. A gate of the changing switch 205 is applied with a select signal RE. The potential generation circuit 206 is connected to the other of source or drain of the changing switch 205 and the capacitor 204 through the changing switch 205.

A charge amount that the capacitor 204 stores is such charge amount of the capacitor 204 that the potential of the bit line becomes the reference potential Vref when charge share is performed between the bit line connected to the plurality of sense amplifiers 203 and the capacitor 204. The changing switch 205 is an N-channel transistor. A potential that the potential generation circuit 206 applies may be the power supply potential VDD, or the potential acquired by decreasing the power supply potential VDD using a voltage driver circuit.

[Reading by Precharging with the Ground Potential VSS (Case1; Equalizing Potential Level)]

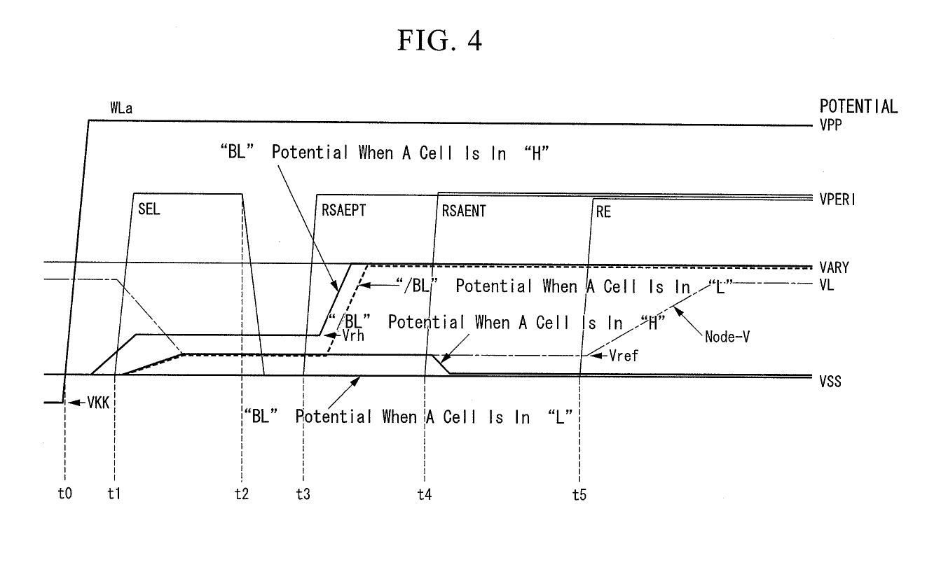

A first behavior of reading of data from the memory cell 212 in accordance with the first embodiment will be described. FIG. 4 is a timing chart illustrating an outline of a signal transition in the first behavior of reading. The longitudinal axis denotes the potential and the horizontal axis denotes the time. The following description is about reading of data from the memory mat 200a of the FIG. 3 where all of the row select signals RFnTm are in “H” level.

The X decoder/X timing generating circuit 802 switches the changing switch 205 “on”, and the capacitor 204 stores charge equal to the storage potential VL. The X decoder/X timing generating circuit 802 has the changing switch 205 turn “off”. The sub-word driver circuits 302 applies a potential VKK that is lower than both of the ground potential VSS and zero voltage to the word line WLa. The memory cells 212 and the bit lines BL and /BL corresponding to the memory cell 212 are disconnected. The X control circuit 31 precharges the bit lines BL and /BL, the higher-potential drive wiring SAP and the lower-potential drive wiring SAN that are connected to the sense amplifier 203. The potential of the bit lines BL and /BL, the higher-potential drive wiring SAP and the lower-potential drive wiring SAN become equal to the ground potential VSS (equalizing potential level) by the precharging.

In a time period t0, the X decoder/X timing generating circuit 802 performs control of the sub-word driver circuit 302 applying an increased potential VPP to the word line WLa. All of the memory cells 212 in the memory mats 200a are respectively connected to the corresponding bit lines BL. The increased potential VPP is higher than the power supply potential VDD and is increased by a charge pump for example. The increased potential VPP may be the power supply potential VDD.

In some cases, the high level “H” may represent “1” of data to be stored in a memory cell, and the low level “L” may represent “0” of data to be stored in the memory cell. When data recorded in the memory cell 212 is in “H” level, that is, when potential of the memory cell capacitor 211 in the memory cell 212 is equal to the higher potential VARY, the memory cell capacitor 211 and the bit line BL are connected through the word line WLa and charge share is performed. Then charge stored in the memory cell capacitor 211 moves to the bit line BL and potential of the bit line BL increases to a read potential Vrh.

When data recorded in the memory cell 212 is in “L” level, that is, when a potential of the memory cell capacitor 211 in the memory cell 212 is equal to the ground potential VSS, the memory cell capacitor 211 and the bit line BL are connected through the word line WLa and charge share is performed. Then charge stored in the memory cell capacitor 211 and charge of the bit line BL are equal to the ground potential VSS, and are not changed by the charge share.

In a time period t1, the X decoder/X timing generating circuit 802 performs control of the X control circuit 31 applying a peripheral potential VPERI to the bit line select signals SELj and SELj′ using the reference activating signal RSELT. The bit line /BL connected to the sense amplifier 203 is connected to the node line Node-V and charge share is performed. Charges stored in the capacitor 204 and the node line Node-V move to the bit line /BL. The bit lines /BLa, /BLc, /BLe, /BLg, - - - have charge-shared potentials between potentials of the bit lines /BLa, /BLc, /BLe, /BLg, - - - and the potential of the node line Node-V charged in the capacitor 204, the potentials of the bit lines /BLa, /BLc, /BLe, /BLg,- - - corresponding to the potential being equalized by the precharge signal BLEQ. A potential of the bit line /BL increases and a potential of the node line Node-V decreases. The potential of the bit line /BL is equal to the reference potential Vref. The peripheral potential VPERI is applied to a peripheral circuit used in other than the memory cell 212. The peripheral potential VPERI is higher than the higher potential VARY and lower than the increased potential VPP. The reference potential Vref is lower than the higher potential VARY and higher than the ground potential VSS. The activation of the bit line select signals SELj and SELj′ can be started before or at the time period t0 that is before the time period t1. In this case, the time of starting the activation must not overlap the time of equalizing from an activated state to an inactivated state of the precharge signal BLEQ.

In a time period t2, the X decoder/X timing generating circuit 802 disconnects the bit line /BL from the node line Node-V based on the bit line select signal SELj and SELj′ after potential of the bit line /BL becomes stable. When the memory mat 200a is selected, the bit line select signals SELj and SELj′ are changed based on the reference activating signal RSELT from the X decoder/X timing generating circuit 802.

Performance of the X decoder/X timing generating circuit 802 may not be related to potential of the bit line /BL. The bit line /BL may be connected to the node line Node-V for a previously decided period based on the bit line select signals SELj and SELj′.

In a time period t3, the X decoder/X timing generating circuit 802 applies the peripheral potential VPERI to the sense amplifier activating signal RSAEPT, and performs control of the X control circuit 31 applying the higher potential VARY to the higher-potential drive wiring SAP. In this way, the sense amplifier 203 changes one of the bit line of higher potential of the bit lines BL and /BL to the higher potential VARY.

When data recorded in the memory cell 212 is in “H” level, the sense amplifier 203 changes potential of the bit line BL to the higher potential VARY. When data recorded in the memory cell 212 is in “L” level, the sense amplifier 203 changes potential of the bit line /BL to the higher potential VARY.

In a time period t4, the X decoder/X timing generating circuit 802 applies the peripheral potential VPERI to the sense amplifier activating signal RSAENT, and performs control of the X control circuit 31 applying the ground potential VSS to the lower-potential drive wiring SAN.

When data recorded in the memory cell 212 is in “H” level, the sense amplifier 203 changes potential of the bit line /BL to the higher potential VARY. When data recorded in the memory cell 212 is in “L” level, the potential of the bit line BL remains the ground potential VSS.

After potentials of the bit lines BL and /BL become stable, the data latch circuit 805 reads data of potentials of the bit lines BL and /BL and data recorded in the memory cell 212 is output from the semiconductor memory device 1 through the input output interface 806.

In a time period t5, the X decoder/X timing generating circuit 802 applies the peripheral potential VPERI to the select signal RE, connects the potential generation circuit 206 with the capacitor 204, and charges the capacitor 204. Charging time of the capacitor 204 is better if shorter than the time between first reading of data and second reading of data in the memory cell 212. In general, the charging time is better if shorter than low cycle period. The X decoder/X timing generating circuit 802 performs control of the X control circuit 31 applying the higher potential VARY to the higher-potential drive wiring SAP and applying the ground potential VSS to the lower-potential drive wiring SAN.

[Reading by Precharging with the Higher Potential VARY (Case2; Equalizing Potential Level)]

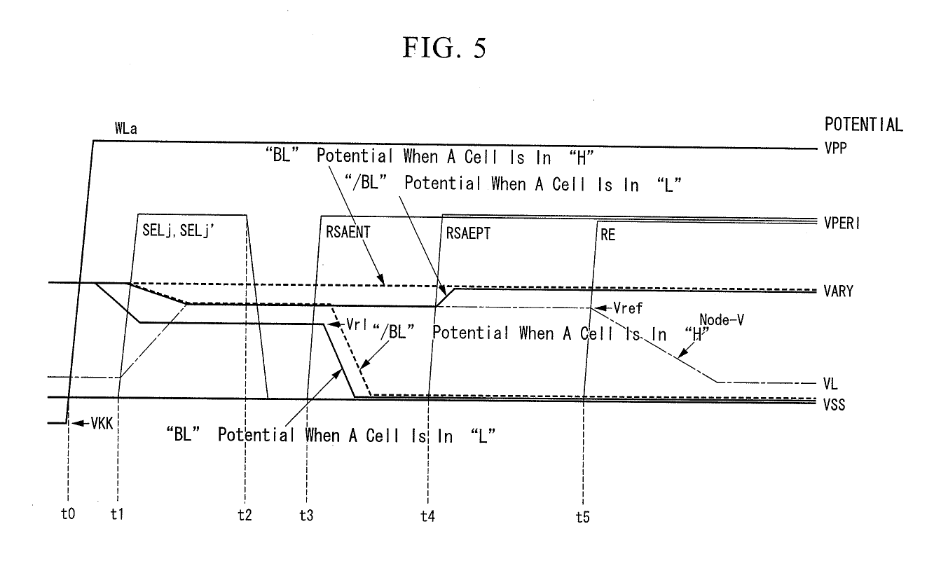

A second behavior of reading of data from the memory cell 212 in accordance with the first embodiment will be described. FIG. 5 is a timing chart illustrating an outline of a signal transition in the second behavior of reading. The longitudinal axis denotes the potential and the horizontal axis denotes the time. Here, the bit lines BL and /BL, the higher-potential drive wiring SAP and the lower-potential drive wiring SAN are precharged with the higher potential VARY (equalizing potential level). So the higher potential VARY is applied to either of sources or drains of N-channel transistors 232, 233, 322 and 323 that are connected to the ground in FIG. 2. The following description is about reading of data from the memory mat 200a of the FIG. 3. That is when the data recorded in the memory cell 212 is in “H” level, and all of the row select signals RFnTm are signals corresponding to the data recorded in the memory cell 212 of “H” level.

The X decoder/X timing generating circuit 802 switches the changing switch 205 “on”, and the capacitor 204 stores charge equal to the storage potential VL. Then the X decoder/X timing generating circuit 802 switches the changing switch 205 “off”. The sub-word driver circuits 302 applies a potential VKK that is lower than the ground potential VSS and zero voltage to the word line WLa. The memory cells 212 and the bit lines BL and /BL corresponding to the memory cell 212 are disconnected. The X control circuit 31 precharges the bit lines BL and /BL, the higher-potential drive wiring SAP and the lower-potential drive wiring SAN that are connected to the sense amplifier 203. Potential of the bit lines BL and /BL, the higher-potential drive wiring SAP and the lower-potential drive wiring SAN become equal to the higher potential VARY by the precharging.

In a time period t0, the X decoder/X timing generating circuit 802 performs control of the sub-word driver circuit 302 applying an increased potential VPP to the word line WLa. This control switches the memory cell transistor 210 in the memory cell 212 “on”. All of the memory cells 212 in the memory mats 200a are respectively connected to the corresponding bit lines BL.

When data recorded in the memory cell 212 is in “H” level, that is, when potential of the memory cell capacitor 211 in the memory cell 212 is equal to the higher potential VARY, the memory cell capacitor 211 and the bit line BL are connected by the word line WLa and charge share is performed. Charge stored in the memory cell capacitor 211 and charge of the bit line BL are equal to the higher potential VARY, and are not changed by the charge share.

When data recorded in the memory cell 212 is in “L” level, that is, when potential of the memory cell capacitor 211 in the memory cell 212 is equal to the ground potential VSS, the memory cell capacitor 211 and the bit line BL are connected by the word line WLa and charge share is performed. Then charge stored in the bit line BL moves to the memory cell capacitor 211 and potential of the bit line BL decreases to a read potential Vr1.

In a time period t1, the X decoder/X timing generating circuit 802 performs control of the X control circuit 31 applying a peripheral potential VPERI to the bit line select signals SELj and SELj′ based on the reference activating signal RSELT. The bit line /BL is connected to the sense amplifier 203 and also connected to the node line Node-V and charge share is performed. Charge stored in the bit line /BL moves to the capacitor 204 and the node line Node-V. A potential of the bit line /BL decreases and a potential of the node line Node-V increases. The potential of the bit line /BL is equal to the reference potential Vref′.

In a time period t2, the X decoder/X timing generating circuit 802 disconnects the bit line /BL from the node line Node-V based on the bit line select signal SELj and SELj′ after potential of the bit line /BL becomes stable. When the memory mat 200a is selected, the bit line select signals SELj and SELj′ change based on the reference activating signal RSELT from the X decoder/X timing generating circuit 802.

In a time period t3, the X decoder/X timing generating circuit 802 applies the peripheral potential VPERI to the sense amplifier activating signal RSAENT, and performs control of the X control circuit 31 applying the ground potential VSS to the lower-potential drive wiring SAN. In this way, the sense amplifier 203 changes one of the bit line of lower potential of the bit lines BL and /BL to the ground potential VSS. When data recorded in the memory cell 212 is in “H” level, the sense amplifier 203 changes a potential of the bit line /BL to the ground potential VSS. When data recorded in the memory cell 212 is in “L” level, the sense amplifier 203 changes a potential of the bit line BL to the ground potential VSS.

In a time period t4, the X decoder/X timing generating circuit 802 applies the peripheral potential VPERI to the sense amplifier activating signal RSAEPT, and performs control of the X control circuit 31 applying the higher potential VARY to the higher-potential drive wiring SAP. When data recorded in the memory cell 212 is in “H” level, the sense amplifier 203 changes potential of the bit line BL to the higher potential VARY. When data recorded in the memory cell 212 is in “L” level, the sense amplifier 203 changes potential of the bit line /BL to the higher potential VARY. After potentials of the bit lines BL and /BL become stable, the data latch circuit 805 reads data of potentials of the bit lines BL and /BL and data recorded in the memory cell 212 is output from the semiconductor memory device 1 through the input output interface 806.

In a time period t5, the X decoder/X timing generating circuit 802 applies the peripheral potential VPERI to the select signal RE, connects the potential generation circuit 206 with the capacitor 204, and charges the capacitor 204. Charging time of the capacitor 204 is better if shorter than the time between first reading of data and second reading of data in the memory cell 212. In general, the charging time is better if shorter than low cycle period. The X decoder/X timing generating circuit 802 performs control of the X control circuit 31 applying the higher potential VARY to the higher-potential drive wiring SAP and applying the ground potential VSS to the lower-potential drive wiring SAN.

As described above, in the first and second behaviors precharging the bit lines BL and /BL with the higher potential VARY or the ground potential VSS, the reference potential is generated by charge share between the bit line /BL and the capacitor 204. The charge share is performed by connecting the bit line /BL to the capacitor 204 after the precharging. By disposing the memory capacitor 204 that has larger capacitance than the memory cell capacitor 211 out of the memory mat 200, the reference potential becomes stable and has little variation caused in fabrication processes. Area of the memory mat 200 is smaller than the prior art that uses the dummy cell because the capacitor 204 is disposed out of the memory mat 200. The optimization of layout area is easy and chip size can be decreased.

Method of setting a capacitance CL and a storage potential VL of the capacitor 204 disposed on the potential generation unit 25 will be described. More specifically, a case of reading by precharging potential of the bit lines BL and /BL with the higher potential VARY will be described.

Sum of charges of the memory cell capacitor 211 and the bit line BL are constant before and after charge share between the memory cell capacitor 211 and the bit line BL based on law of conservation of charge. So a capacitance Cs of the memory cell capacitor 211 and a capacitance Cb of the bit line BL satisfy the following equations (1-1) and (1-2). Here, V1H represents potential of the memory cell 212 when data of “H” level is recorded, and V1L represents potential of the memory cell 212 when data of “L” level is recorded.

Cb·VARY+Cs·VARY=(Cb+Cs)V1H (1-1)

Cb·VARY=(Cb+Cs)V1L (1-2)

Hence the potential V1H and V1L are given by the following equations (2-1) and (2-2).

V1H=VARY (2-1)

V1L=Cb·VARY/(Cb+Cs) (2-2)

When the number of the sense amplifiers 203 that are selected is n, sum of charges of the n bit lines /BL and the capacitor 204 are constant before and after charge share between the n bit lines /BL and the capacitor 204 in the same way. Hence the following equation (3) is satisfied, where V2 represents potential after the charge share.

n·Cb·VARY+CL·VL=(n·Cb+CL)V2 (3)

Here, when the following equation (4) is satisfied, the sense amplifier 203 has the same detection characteristic whether data that is recorded in the memory cell 212 is in “H” level or “L” level.

V2=(V1H+V1L)/2 (4)

The following equation (5) is given by solving the equations (2-1), (2-2), (3) and (4), showing relationship between the capacitance CL and the storage potential VL.

CL=n·Cb·(α−VARY)/(VL−α) (5)

where α=VARY·(Cs+2·n·Cb)/(Cs+n·Cb)/2

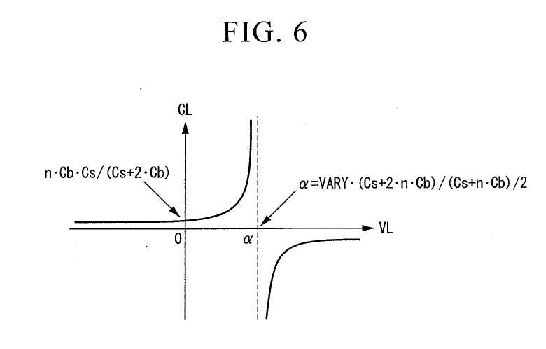

FIG. 6 is a graph showing the relationship between the capacitance CL and the storage potential VL. The graph is inversely proportional. When the storage potential VL is between 0 and α, the sense amplifier 203 has same detection characteristic whether data that is recorded in the memory cell 212 is in “H” level or “L” level by disposing the capacitor 204 that has the capacitance CL satisfying the equation (5).

The equation (5) gives relationship between the capacitance CL and the storage potential VL. From the equation (5), the potential V2 that causes constant difference between the reference potential and potential of the bit line BL is given whether data recorded in the memory cell 212 is in “H” level or “L” level. When the potential V2 is higher than the average of the V1H and V1L, the difference between the potential of the bit line BL and the reference potential decreases when data recorded in the memory cell 212 is in “H” level. When the potential V2 is lower than the average of the V1H and V1L, the difference between the potential of the bit line BL and the reference potential decreases when data recorded in the memory cell 212 is in “L” level. From the equation (3), the potential V2 and the storage potential VL are in proportional relation. By setting the storage potential VL high, the potential V2 can be set high. By setting the storage potential VL low, the potential V2 can be set low.

In adjusting the reference potential, the reference potential is set higher than the read potential Vr1 when the bit lines BL and /BL are precharged with the higher potential VARY and data recorded in the memory cell 212 is in “L” level. The reference potential is set lower than the read potential Vrh when the bit lines BL and /BL are precharged with the ground potential VSS and data recorded in the memory cell 212 is in “H” level. When the bit lines BL and /BL are precharged with the ground potential VSS, reading behavior is performed by setting capacitance of the capacitor 204 and the storage potential VL based on relationship between the capacitance CL and the storage potential VL.

As described above, detection margin of the sense amplifier 203 can be adjusted by adjusting the storage potential VL and optimization of the detection margin can be performed after fabrication of the semiconductor memory device 1. Speed test as a reliability test can be performed by changing the storage potential VL.

### Second Embodiment

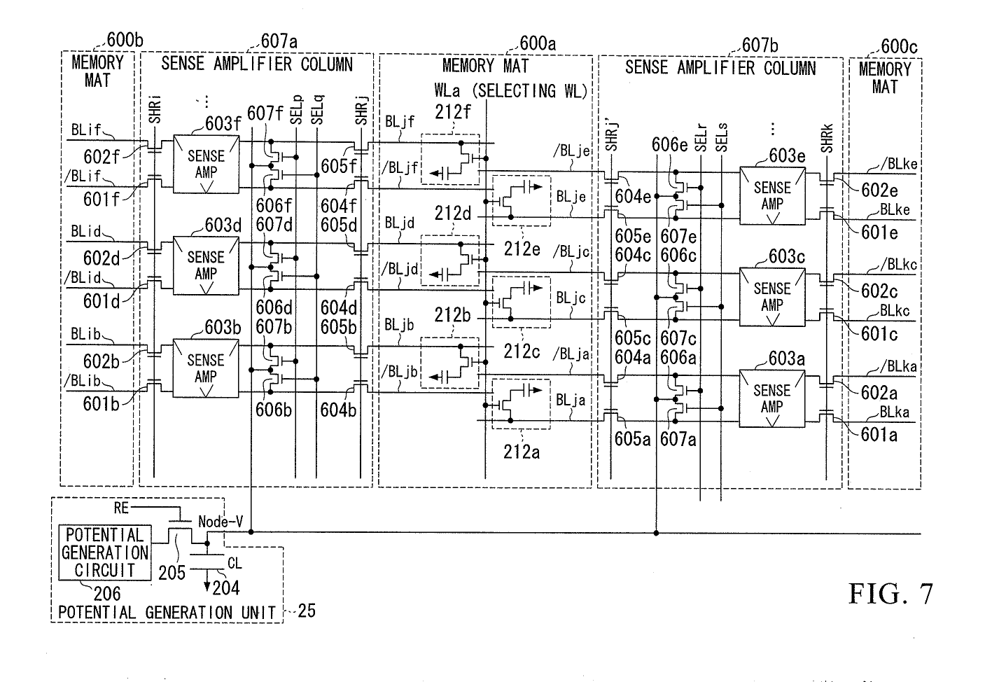

Another connection between the memory mat and the sense amplifier column will be described as a second embodiment of the present invention. FIG. 7 is a view of a block diagram illustrating a configuration of memory mats 600a, 600b and 600c that are arranged in a folded bit line configuration, sense amplifier columns 607a and 607b and the potential generation unit 25, and illustrating a connection between the memory mats 600a, 600b and 600c, the sense amplifier columns 607a and 607b and the potential generation unit 25 in accordance with the second embodiment. Here, the folded bit line configuration is such configuration that has paired bit lines of a first bit line connected to memory cell and a second bit line that generates reference potential corresponding to the first bit line disposed on the same memory mat. The memory mats 600a, 600b and 600c have same configuration. The sense amplifier columns 607a and 607b have same configuration. The potential generation unit 25 has the same configuration as that of FIG. 2, so description of the potential generation unit 25 will be omitted.

The memory mat 600a is disposed between the sense amplifier columns 607a and 607b. The memory mat 600b is disposed on the opposite side of the memory mat 600a, the memory mats 600a and 600b sandwiching the sense amplifier column 607a. The memory mat 600c is disposed on the opposite side of the memory mat 600a, the memory mats 600a and 600c sandwiching the sense amplifier column 607b.

The memory mat 600a includes a plurality of memory cells 212a, 212b, 212c, - - - . The memory mat 600a includes paired bit lines {BLja, /BLja}, {BLjb, /BLjb}, {BLjc, /BLjc}, - - - corresponding to the plurality of memory cells 212a, 212b, 212c, - - - . The plurality of memory cells 212a, 212b, 212c, - - - have same configuration as that of FIG. 3, so description of the memory cells 212a, 212b, 212c, - - - will be omitted.

The paired bit lines {BLja, /BLja}, {BLjb, /BLjb}, {BLjc, /BLjc}, - - - are connected to either the sense amplifier column 607a or the sense amplifier column 607b alternately. The gates of the memory cell transistors 210 of the memory cells 212a, 212b, 212c, - - - are connected to the word line WLa. Either of sources or drains of the memory cell transistors 210 of the memory cells 212a, 212b, 212c, - - - are connected to the bit lines BLj corresponding to the memory cells, and the other of sources or drains of the memory cell transistors 210 of the memory cells 212a, 212b, 212c, - - - are connected to the ground.

The memory mat 600b are connected to the sense amplifier column 607a by paired bit lines {BLkb, /BLkb}, {BLkd, /BLkd}, {BLkf, /BLkf}, - - - . The memory mat 600c is connected to the sense amplifier column 607b by paired bit lines {BLka, /BLka}, {BLkc, /BLkc}, {BLke, /BLke}, - - - .

The sense amplifier column 607a includes a plurality of sense amplifiers 603b, 603d, 603f, - - - , bit line changing transistors 601b, 601d, 601f, - - - , bit line changing transistors 602b, 602d, 602f, - - - , bit line changing transistors 604b, 604d, 604f, - - - , bit line changing transistors 605b, 605d, 605f, connecting transistors 606b, 606d, 606f, - - - and connecting transistors 607b, 607d, 607f, - - - .

The sense amplifier 603b is connected to the bit line BLjb in the memory mat 600a by the bit line changing transistor 605b. The sense amplifier 603b is connected to the bit line /BLjb in the memory mat 600a by the bit line changing transistor 604b. The sense amplifier 603b is connected to the bit line BLib in the memory mat 600b by the bit line changing transistor 602b. The sense amplifier 603b is connected to the bit line /BLib in the memory mat 600b by the bit line changing transistor 601b. The bit line changing transistors 601b and 602b define whether to connect the paired bit lines BLib and /BLib to the sense amplifier 603b based on a memory mat select signal SHRi input from gate of the bit line changing transistors 601b and 602b. The bit line changing transistors 604b and 605b define whether to connect the paired bit lines BLjb and /BLjb to the sense amplifier 603b based on a memory mat select signal SHRj input from gate of the bit line changing transistors 604b and 605b.

The connecting transistor 606b is disposed between the bit line changing transistor 604b and the sense amplifier 603b (or the bit line changing transistor 601b). One of source or drain of the connecting transistor 606b is connected to the bit line /BLjb, and the other of source or drain of the connecting transistor 606b is connected to the node line Node-V. A gate of the connecting transistor 606b is connected to a bit line select signal SELq. The connecting transistor 607b is disposed between the bit line changing transistor 605b and the sense amplifier 603b (or the bit line changing transistor 602b). One of source or drain of the connecting transistor 607b is connected to the bit line BLjb, and the other of source or drain of the connecting transistor 606b is connected to the node line Node-V. A gate of the connecting transistor 607b is connected to a bit line select signal SELp. The connecting transistor 606b define whether to connect the bit line /BLjb to the node line Node-V based on the bit line select signal SELq input from gate of the connecting transistor 606b. The connecting transistor 607b defines whether to connect the bit line BLjb to the node line Node-V based on the bit line select signal SELp input from the gate of the connecting transistor 607b.

The sense amplifier 603b has same configuration as the sense amplifier 203a of FIG. 2. The bit line BLjb in the memory mat 600a is connected to the bit line BLib in the memory mat 600b. The bit line /BLjb in the memory mat 600a is connected to the bit line /BLib in the memory mat 600b. That is, the sense amplifier 603b is connected to two memory cells next to the sense amplifier 603b by paired bit lines corresponding to the memory cells. The sense amplifiers 603d, 603f, - - - are connected to bit lines like the sense amplifier 603b. The memory mat select signals SHRi and SHRj and the bit line select signals SELp and SELq are used in common in the sense amplifiers 603b, 603d, 603f, - - - .

The sense amplifier column 607b includes a plurality of sense amplifiers 603a, 603c, 603e, - - - , bit line changing transistors 601a, 601c, 601e, - - - , bit line changing transistors 602a, 602c, 602e, - - - , bit line changing transistors 604a, 604c, 604e, - - - , bit line changing transistors 605a, 605c, 605e, connecting transistors 606a, 606c, 606e, - - - and connecting transistors 607a, 607c, 607e, - - - .

The sense amplifier 603a is connected to the bit line BLja in the memory mat 600a by the bit line changing transistor 605a. The sense amplifier 603a is connected to the bit line /BLja in the memory mat 600a by the bit line changing transistor 604a. The sense amplifier 603a is connected to the bit line /BLka in the memory mat 600c by the bit line changing transistor 602a. The sense amplifier 603a is connected to the bit line BLka in the memory mat 600c by the bit line changing transistor 601c.

The bit line changing transistors 601a and 602a define whether to connect the paired bit lines BLka and /BLka to the sense amplifier 603a based on a memory mat select signal SHRk input from gate of the bit line changing transistors 601a and 602a. The bit line changing transistors 604a and 605a define whether to connect the paired bit lines BLja and /BLja to the sense amplifier 603a based on a memory mat select signal SHRj′ input from gate of the bit line changing transistors 604a and 605a.

The connecting transistor 606a is disposed between the bit line changing transistor 604a and the sense amplifier 603a (or the bit line changing transistor 602a). One of source or drain of the connecting transistor 606a is connected to the bit line /BLja, and the other of source or drain of the connecting transistor 606a is connected to the node line Node-V. A gate of the connecting transistor 606a is connected to a bit line select signal SELr. The connecting transistor 607a is disposed between the bit line changing transistor 605a and the sense amplifier 603a (or the bit line changing transistor 601a). One of source or drain of the connecting transistor 607a is connected to the bit line BLja, and the other of source or drain of the connecting transistor 606a is connected to the node line Node-V. A gate of the connecting transistor 607a is connected to a bit line select signal SELs. The connecting transistor 606a defines whether to connect the bit line /BLja to the node line Node-V based on the bit line select signal SELr input from gate of the connecting transistor 606a. The connecting transistor 607a defines whether to connect the bit line BLja to the node line Node-V based on the bit line select signal SELs input from gate of the connecting transistor 607a.

The sense amplifier 603a has same configuration as the sense amplifier 203a of FIG. 2. The bit line BLja in the memory mat 600a is connected to the bit line BLka in the memory mat 600b. The bit line /BLja in the memory mat 600a is connected to the bit line /BLka in the memory mat 600b. That is, the sense amplifier 603a is connected to two memory cells next to the sense amplifier 603a by paired bit lines corresponding to the memory cells. The sense amplifiers 603c, 603e, - - - are connected to bit lines like the sense amplifier 603a. The memory mat select signals SHRj′ and SHRk and the bit line select signals SELr and SELs are used in common in the sense amplifiers 603a, 603c, 603e, - - - .

The memory mat select signal SHRi switches on/off of connection between the memory mat 600b and the sense amplifier column 607a. When the memory mat 600b is selected, the X decoder/X timing generating circuit 802 performs control of the memory mat signal SHRi to cause data recorded in the memory cell in the memory mat 600b to be in “H” level, and connects the memory mat 600b to the sense amplifier column 607a by paired bit lines {BLib, /BLib}, {BLid, /BLid}, {BLif, /BLif}, - - - , and the X decoder/X timing generating circuit 802 performs control of the memory mat signal SHRj to be in “L” level, thereby the memory mat 600a is electrically-disconnected with the sense amplifier column 607a.

The memory mat select signal SHRj switches on/off of connection between the memory mat 600a and the sense amplifier column 607a. When the memory mat 600a is selected, the X decoder/X timing generating circuit 802 performs control of the memory mat signals SHRj and SHRj′ to cause data recorded in the memory cell 212 to be in “H” level, and connects the memory mat 600a to the sense amplifier columns 607a and 607b by paired bit lines {BLja, /BLja}, {BLjb, /BLjb}, - - - , and the X decoder/X timing generating circuit 802 performs control of the memory mat signals SHRi and SHRk to be in “L” level, thereby the memory mats 600b and 600c are respective electrically-disconnected with the sense amplifier column 607a and 607b.

The memory mat select signal SHRk switches on/off of connection between the memory mat 600c and the sense amplifier column 607b. When the memory mat 600c is selected, the X decoder/X timing generating circuit 802 performs control of the memory mat signal SHRk to cause data recorded in the memory cell 212 to be in “H” level, and connects the memory mat 600c to the sense amplifier columns 607b and 607b by paired bit lines {BLka, /BLka}, {BLkc, /BLkc}, {BLke, /BLke} - - - , and the X decoder/X timing generating circuit 802 performs control of the memory mat signal SHRj′ to be in “L” level, thereby the memory mat 600a is electrically-disconnected with the sense amplifier column 607b.

A behavior of reading of data from the memory cell 212 in accordance with the second embodiment is same as that of FIG. 4 and FIG. 5. The word line WLa is selected, and the X decoder/X timing generating circuit 802 connects the memory mat 600a to the sense amplifier columns 607a and 607b by the memory mat select signals SHRj and SHRj′. As described above, the folded bit line configuration can be used connected to the potential generation unit 25.

As described in the first and second embodiments, the potential generation unit 25 need not be disposed on limited area of memory mat 810 by minute processing techniques. Capacitance of the capacitor 204 is larger than that of dummy cell capacitor used in the conventional dummy cell, so the capacitor 204 with stable capacitance can be fabricated. Even after fabrication, capacitance of the capacitor 204 can be adjusted to set the reference potential by disposing extra capacitors for adjusting the capacitance.

Even if potential of the memory array 801 is decreased by minute processing techniques, stable reference potential can be input to the sense amplifier 203 using capacitor with constant charge and speed of reading can be stable. As a result, decrease in performance can be avoided. Because the potential generation unit 25 is disposed out of the memory array 801, layout of chips in the potential generation unit 25 can be optimized easily based on shape of chips. As a result, chip size can be decreased.

The potential generation unit 25 may be disposed on each of the memory banks Bank 0, Bank 1, - - - , Bank m. Then the potential generation unit 25 can adjust the reference potential respectively in each of the memory banks Bank 0, Bank 1, - - - , Bank m. And the potential generation unit 25 can adjust reading speed in each of the memory banks Bank 0, Bank 1, - - - , Bank m. Then trace between the potential generation unit 25 and the sense amplifier 203 becomes short. As a result, charge storage of the capacitor 204 becomes small and time for charge storage can be decreased.

Detecting speed of the sense amplifier 203 can be made faster using a conventional overdrive scheme disclosed in Japanese Patent Application No. 2008-16145. The peripheral potential VPERI and the higher potential VARY may use the power supply potential VDD instead of potential caused by decreasing voltage of the power supply potential VDD. In this case, the voltage divider circuit is not needed. As a result, chip size can be decreased.

The above description is about the semiconductor memory device. The invention is not limited to the semiconductor memory device. The invention is applied to every device with memory functions. The invention is obviously applied to devices with active functions including memory function units of semiconductor device such as CPU, MCU, DSP and so on. The invention may be applied to semiconductor recording devices or semiconductor devices such as including memory cells such as SOS (System On Chip), MCP (Multi Chip Package), POP (Package On Package) and so on.

The transistor of the invention is not limited to MOS transistor, but applied to every kind of FET (Field Effect Transistor) such as MIS (Metal-Insulator Semiconductor), TFT (Thin Film Transistor) and so on. The transistor may be bipolar junction transistor. The N-channel transistor is a NMOS transistor and represents a first conductivity type transistor. The P-channel transistor is a PMOS transistor and represents a second conductivity type transistor.

It is apparent that the present invention is not limited to the above embodiments, but may be modified and changed without departing from the scope and spirit of the invention.

What is claimed is:

1. A semiconductor memory device comprising:
a plurality of first bit lines;
a plurality of second bit lines, each of the plurality of second bit lines being complementary to a respective one of the plurality of first bit lines;
a plurality of sense amplifiers, each of the plurality of sense amplifiers being connected to a respective one of pairs of the first and second bit lines;
a plurality of memory cells, each of the plurality of memory cells being connected to a respective one of the plurality of first bit lines;
a plurality of first switches, each of the plurality of first switches being connected to a respective one of the plurality of first bit lines;
a plurality of second switches, each of the plurality of second switches being connected to a respective one of the plurality of second bit lines;
an equalizer circuit that is connected to the plurality of first and second bit lines; and
a potential generation unit that is connected to the plurality of first bit lines through the plurality of first switches, the potential generation unit being connected to the plurality of second bit lines through the plurality of second switches, the potential generation unit supplying a first potential to at least a selected one of the plurality of first and second bit lines through the plurality of first and second switches,
wherein, the equalizer circuit sets the plurality of first and second bit lines at a second potential,
when each of the plurality of memory cells is selected, the potential generation unit applies the first potential to a corresponding second bit line through a corresponding second switch, the corresponding second bit line being paired with a corresponding first bit line, the corresponding first bit line being connected to the selected memory cell, the corresponding second switch being connected to the corresponding second bit line,
a corresponding sense amplifier performs sensing of a third potential of the corresponding first bit line and a fourth potential of the corresponding second bit line, the corresponding sense amplifier being connected to the corresponding first and second bit lines, the third potential being a potential charge-shared between an information potential of the selected memory cell and the first potential, the fourth potential being a potential charge-shared between the first potential and total of all the second potentials of all the plurality of second bit lines.

2. The semiconductor memory device according to claim 1, wherein the potential generation unit comprises a capacitor that is charged at a third potential different from the first potential.

3. The semiconductor memory device according to claim 2, wherein the capacitor supplies charges to the plurality of second bit lines.

4. The semiconductor memory device according to claim 3, wherein the capacitor is charged before the access is made to the memory cell.

5. The semiconductor memory device according to claim 2, wherein the first potential is a potential at which the capacitor is charge-shared with the total of the plurality of second bit lines when the plurality of second bit lines that had been charged at the second potential have been connected commonly to the capacitor.

6. The semiconductor memory device according to claim 2, wherein the first potential is a half of the total of different potentials of the plurality of first bit lines, the different potentials respectively corresponding binary information 0 and 1 of the plurality of memory cells.

7. The semiconductor memory device according to claim 6, wherein the second potential is a potential corresponding to binary information 0 or 1 of the plurality of memory cells.

8. The semiconductor memory device according to claim 2, wherein the plurality of first and second bit lines have an open bit line configuration that the plurality of first and second bit lines are disposed on different memory mats based on the arrangement of the plurality of sense amplifiers.

9. The semiconductor memory device according to claim 2, wherein the plurality of first and second bit lines have a folded bit line configuration that the plurality of first and second bit lines are disposed on the same memory mat based on the arrangement of the plurality of sense amplifiers.

10. The semiconductor memory device according to claim 2, wherein the capacitor is disposed out of a memory mat having the plurality of memory cells and out of a sense amplifier column on which the plurality of sense amplifiers is disposed.

11. A semiconductor memory device comprising:
a plurality of memory cells;
a plurality of first bit lines, each of the plurality of first bit lines transmitting information of a respective one of the plurality of memory cells;
a plurality of second bit lines, each of the plurality of second bit lines performing as a reference potential line that is needed in sensing of a respective one of the plurality of first bit lines;
a plurality of sense amplifiers, each of the plurality of sense amplifiers connected to a respective one of the plurality of first bit lines and a respective one of the plurality of second bit lines;
a plurality of switches, each of the plurality of switches connected to a respective one of the plurality of second bit lines; and
a potential generation unit that is connected to the first side of each of the plurality of switches, and
wherein the potential generation unit comprises a capacitor that accumulates an amount of charge, the capacitor is to be charge-shared with a total amount of charges of the plurality of second bit lines,
the second bit line is set at a first potential when the plurality of switches turn ON, the first potential is a half of the total of different potentials of the plurality of first bit lines, the different potentials respectively corresponding binary information 0 and 1 of the plurality of memory cells.

12. The semiconductor memory device according to claim 11, wherein each of the plurality of switches turns ON when an access is made to a respective one of the plurality of memory cells.

13. The semiconductor memory device according to claim 12, wherein when each of the plurality of switches turns ON, a respective one of the plurality of second bit lines is transitioned from a second potential to the first potential, the first potential is a reference potential needed in the sensing of the respective one of the plurality of first bit lines.

14. The semiconductor memory device according to claim 11, wherein the accumulation of charge of the capacitor is performed when no access is made to the plurality of memory cells.

15. The semiconductor memory device according to claim 11, wherein the first potential is a half of the total of different potentials of the plurality of first bit lines, the different potentials respectively corresponding binary information 0 and 1 of the plurality of memory cells.

16. The semiconductor memory device according to claim 15, wherein the second potential is a potential corresponding to binary information 0 or 1 of the plurality of memory cells.

17. The semiconductor memory device according to claim 11, wherein the plurality of first and second bit lines have an open bit line configuration that the plurality of first and second bit lines are disposed on different memory mats based on the arrangement of the plurality of sense amplifiers.

18. The semiconductor memory device according to claim 11, wherein the plurality of first and second bit lines have a folded bit line configuration that the plurality of first and second bit lines are disposed on the same memory mat based on the arrangement of the plurality of sense amplifiers.

19. The semiconductor memory device according to claim 11, wherein the capacitor is disposed out of a memory mat having the plurality of memory cells and out of a sense amplifier column on which the plurality of sense amplifiers is disposed.

20. A semiconductor memory device comprising:
a first bit line;
a second bit line being complementary to the first bit line;
a sense amplifier being connected to a pair of the first and second bit lines;
a memory cell being connected to the first bit line;
a first switch being connected to the first bit line;
a second switch being connected to the second bit line;
an equalizer circuit that is connected to the first and second bit lines; and
a potential generation unit that is connected to the first bit line through the first switch, the potential generation unit being connected to the second bit line through the second switch, the potential generation unit supplying a first potential to at least a selected one of the first and second bit lines through the first and second switches, and
wherein, the equalizer circuit sets the first and second bit lines at the second potential,
potential of the second bit line becomes a charge-shared potential between the first potential and all the second potentials of all the second bit lines, the second bit line being corresponding to the first bit line connected to the memory cell.
